(19) United States
(12) Patent Application Publication
(10) Pub. No.: US 2026/0231757 A1
(43) Pub. Date: Aug. 6, 2026

(54) POWER DELIVERY FOR AI COMPUTING WITH ORTHOGONAL EMBEDDING AND EDGE ACCESS

(71) Applicants: Applied Materials, Inc., Santa Clara, CA (US); The Florida International University Board of Trustees, Miami, FL (US)

(72) Inventors: Mudit Sunilkumar KHASGIWALA, Milpitas, CA (US); Subramani KENGERI, Saratoga, CA (US); Markondeyaraj PULUGURTHA, Miami, FL (US); Mohammad Mohtasim Hamid PIAL, Miami, FL (US); Ghaleb Saleh Ghaleb Al Duhni, Miami, FL (US)

(73) Assignees: Applied Materials, Inc., Santa Clara, CA (US); The Florida International University Board of Trustees, Miami, FL (US)

(21) Appl. No.: 19/045,313

(22) Filed: Feb. 4, 2025

(51) Int. Cl. H01L 23/522; H01L 23/528

(52) U.S. Cl. CPC H10W 20/496; H10W 20/427; H10W 20/497

(57) ABSTRACT

A semiconductor device with a vertically mounted IPD may include a substrate may include a cavity. The device may include a vertically mounted IPD disposed within the cavity. The vertically mounted IPD may include a capacitor including electrical contacts on a vertical edge of the capacitor. The vertically mounted IPD may include an inductor with electrical contacts on a vertical edge of the inductor. The device may include a metal layer in electrical contact on a first edge of the vertically mounted IPD, the first edge in electrical contact with at least one of the electrical contacts on the vertical edge of the capacitor or the electrical contacts on the vertical edge of the inductor. The device may include a device layer in electrical contact with the metal layer. The device may include a backside power delivery network in electrical contact with a second edge of the vertically mounted IPD.

### TECHNICAL FIELD

The present technology relates to semiconductor systems, processes, and equipment. More specifically, the present technology relates to integrated passive devices for use in semiconductors and other electronic devices.

### BACKGROUND

Certain computational operations, such as those associated with artificial intelligence (AI), require high data throughput and efficient power delivery to specialized processing units. At the same time, there is pressure to produce physically smaller devices capable of supporting AI operations. Traditional power delivery system configurations may be able to provide adequate power, but scaling these systems down may lead to unwanted electrical phenomena that render these systems ineffective at frequencies necessary to perform these operations.

### BRIEF SUMMARY

A semiconductor device may include a substrate may including a cavity. The device may include a vertically mounted integrated passive device (IPD) disposed within the cavity of the substrate. The device may include a backside power delivery network, electrically connected to the vertically mounted IPD.

In some embodiments, the vertically mounted IPD may include a capacitor. The capacitor may include at least one of a sintered particle, a metal nanowire, a carbon nanofiber, a silicon trench, a silicon nanowire, an aluminum nanowire, or a carbon nanotube. The capacitor may be a bryce capacitor. The vertically mounted IPD may include at least one of a solenoidal inductor or a toroidal inductor. The vertically mounted IPD may include an inductor-capacitor stack. The vertically mounted IPD may include interconnects on a side that are extended to a top and a bottom side and are configured for backside power delivery.

A method of manufacturing a semiconductor device with a vertically mounted IPD may include providing a substrate may include a cavity. The method may include inserting a vertically mounted IPD in the cavity, such that a first edge of the vertically mounted IPD is in electrical contact with a backside power delivery network (BPDN) of the semiconductor device. The method may include depositing a polymer layer to the cavity such that the vertically mounted IPD and the polymer layer fill the cavity. The method may include forming a third metal layer such that at least a portion of the third metal layer is in electrical contact with the vertically mounted IPD. The method may include connecting a processing unit to the third metal layer.

In some embodiments, the vertically mounted IPD may be a capacitor, and the method may include: forming a first metal layer; depositing a dielectric layer on the first metal layer; and depositing a second metal layer on the dielectric layer to form the capacitor. The method may include forming particles on the first metal layer. The particles may include at least one of fiber-based particles, silica, silica glass, or barium titanate particles. The vertically mounted IPD may be an inductor, and the method may include: providing a flexible core may include a magnetic film; forming a dielectric layer on the magnetic film; and forming a metal layer on at least a portion of the magnetic film to form the inductor. The method may include forming an inductor. The method may include forming a capacitor. The method may include stacking the inductor and capacitor in a unitary body to form the vertically mounted IPD.

A semiconductor device with a vertically mounted IPD may include a substrate may include a cavity. The device may include a vertically mounted IPD disposed within the cavity. The vertically mounted IPD may include a capacitor including electrical contacts on a vertical edge of the capacitor. The vertically mounted IPD may include an inductor with electrical contacts on a vertical edge of the inductor. The device may include a metal layer in electrical contact on a first edge of the vertically mounted IPD, the first edge in electrical contact with at least one of the electrical contacts on the vertical edge of the capacitor or the electrical contacts on the vertical edge of the inductor. The device may include a device layer in electrical contact with the metal layer. The device may include a backside power delivery network in electrical contact with a second edge of the vertically mounted IPD.

In some embodiments, the vertically mounted IPD may include a width within a range of 50 microns to 150 microns, inclusive. The vertically mounted IPD may include a height within a range of 0.5 mm to 1.5 mm, inclusive. The vertically mounted IPD may include a depth within a range of 1 mm to 7 mm, inclusive. The capacitor may be a multilayered ceramic capacitor. The vertically mounted IPD may include a capacitive density within a range of 50 microfarads per millimeter cubed to 200 microfarads per millimeter cubed. The vertically mounted IPD may include an inductance within a range of 100 nanohenry per millimeter square to about 500 nanohenry per millimeter square.

### BRIEF DESCRIPTION OF THE DRAWINGS

FIG. 1 illustrates a flowchart of a method 100 for embedding a vertically mounted IPD in a semiconductor device, according to certain embodiments.

FIGS. 2A-2E illustrate a semiconductor device with a vertically mounted IPD, according to certain embodiments.

FIG. 3 illustrates a flowchart of a method for forming a vertically mounted capacitor, according to certain embodiments.

FIGS. 4A-4I illustrate a capacitor configured to be vertically mounted, according to certain embodiments.

FIG. 5 illustrates a flowchart of a method for forming a vertically mounted inductor, according to certain embodiments.

FIGS. 6A-6H illustrate an inductor configured to be vertically mounted, according to certain embodiments.

FIG. 7 illustrates an IPD array, according to certain embodiments.

FIG. 8 illustrates an exemplary computer system, in which various embodiments may be implemented.

### DETAILED DESCRIPTION

Artificial intelligence (AI) models (or engines) tend to require significant computing power. Early AI engines could be run on standard central processing units. As AI engines grew in capability and complexity, the computational resources required may also grew. Consequently, AI engines are now frequently run on dedicated machines, with specialized processing units with architecture optimized for AI operations. These architectures may include components such as graphics processing units (GPUs), application specific integrated circuits (ASIC), field programmable gate arrays (FPGAs), and/or other components that are optimized for parallel computations with optimized design features. These devices may support more than 100 billion transistors at a density of 25 million transistors/per millimeter square. As such, a high power delivery bandwidth may help increase the speed of performing AI calculations.

Traditionally, certain components (e.g., capacitors and inductors, or “LC” components) of the power delivery network (PDN) are arrayed laterally, with a relatively large length dimension with respect to a height dimension. The lateral arrangement of the LC components may take up valuable under the chip real estate of the package substrate, limiting signal pathways available and capping the performance of the processing unit. In frequencies at or above about 10 MHz, traditional PDNs may experience loop inductances in the 10 picohenry range. To combat this, the components of the PDN may be separated from other components to reduce the effect any one component has on another. While separating the components may mitigate some of these unwanted effects, the LC components, this takes up even more on-chip area. Modern and future semiconductor devices may require LC components with 50 capacitive densities of microfarad/mm 2 and 1000 nF/mm 2 without a loss in efficiency.

Traditional LC components may be limited to lateral mounting within a package for several reasons. One reason may be that the LC components are relatively thick. For example, a typical multilayered ceramic capacitor (MLCC) may be about 1 mm by 0.5 mm with a thickness of 0.5 mm in order to provide a meaningful amount of storage within a PDN. While a thinner capacitor may be possible, the capacitive density of the thinner capacitor may be significantly less than needed. Thus, any advantage in vertically mounting these capacitors (and/or other LC components) may be lost.

Another reason may be that traditional LC components tend to be formed as discreet units, either pre-manufactured and installed in a semiconductor package or formed individually within the semiconductor package. As the LC components are discreet units, each with its own electrical contacts or terminals. This may limit the forms possible using traditional LC components as well as add production complexity by connecting the LC component to produce the desired characteristics. Therefore, thinner LC components with the capability to be vertically mounted (sometimes “edge mounted”) are needed in order to improve power storage density as capacitive and/or inductive density.

Additionally, the space provided for LC components on a substrate (i.e., a chip) may also be limited by manufacturing thresholds, standards etc. The space for embedding LC components on a particular chip may therefore be limited by the substrate manufacturer. For example, a slot (or cavity) for embedding LC components may be 1 mm wide. Only two traditionally mounted LC components may be embedded in the substrate.

One solution may be to utilize thin IPD arrays within a semiconductor device, the IPD arrays vertically mounted within a semiconductor package in order to increase power storage density. A substrate may include a cavity for embedding IPDs. An IPD may then be vertically mounted within the cavity of the substrate. The IPD may include one or more capacitors and/or inductors. The IPD may be prefabricated to include any number of capacitors and/or inductors to form an IPD array. The IPD array may also include multiple terminals disposed on the edges of the IPD array, allowing for multiple connections using the same IPD array. Any space in the cavity not taken by the IPD array may be filled with a dielectric polymer and planarized. Then, metal vias may be formed through the polymer. A device layer such as a processing unit (e.g., a GPU, FPGA, etc.) may then be connected to the semiconductor package, such that the processing unit is electrically connected to at least some of the IPD array. Then, a backside power delivery network (BPDN) may be formed on an opposite side of the substrate/BPDN from the processing unit and connected to the IPD array. By vertically mounting a thin IPD array, greater power storage density may be achieved as compared to traditional IPD layouts.

In some embodiments, the interconnects may be formed in the lateral configuration. Terminations are may be extended to the edge of the device and accessed from the vertical mounting. Therefore, the on-IPD interconnects (sometimes, “on-IPD RDLs”) may be facing to the side while the processor/redistribution layer and backside power delivery network access interconnects will be from the top and/or bottom.

Fabricating thin shallow devices with lateral configuration, and vertical embedding may be beneficial because manufacturing may be easier with shallow cavities. Additionally, hand, vertical embedding may be beneficial over lateral mounting as the device consumes less footprint.

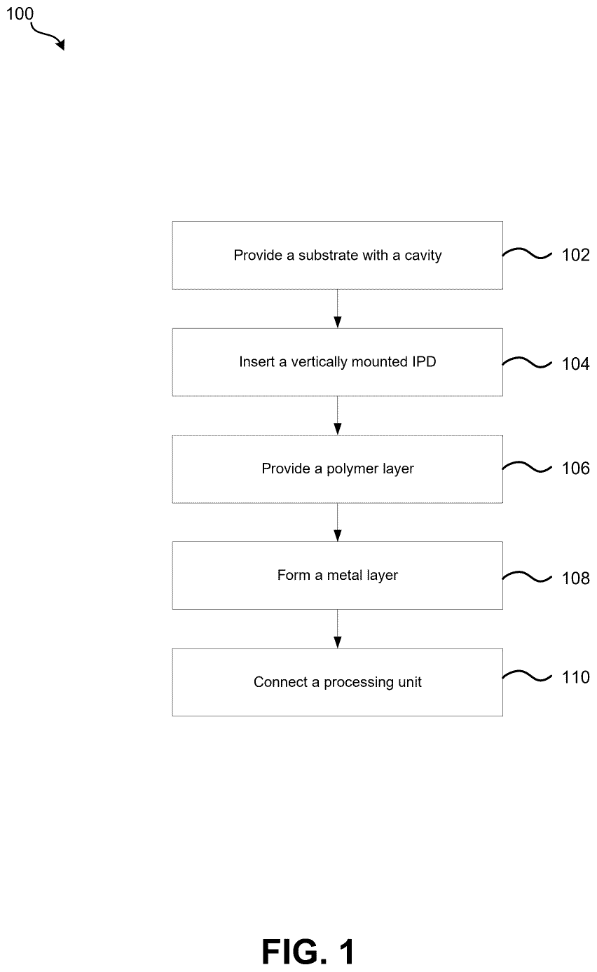

FIG. 1 illustrates a flowchart of a method 100 for embedding a vertically mounted IPD in a semiconductor device, according to certain embodiments. Steps of the method 100 may be performed in a different order than is shown in FIG. 1 and/or combined with other steps of the method 100. In some embodiments, some of the steps of the method 100 may be skipped altogether.

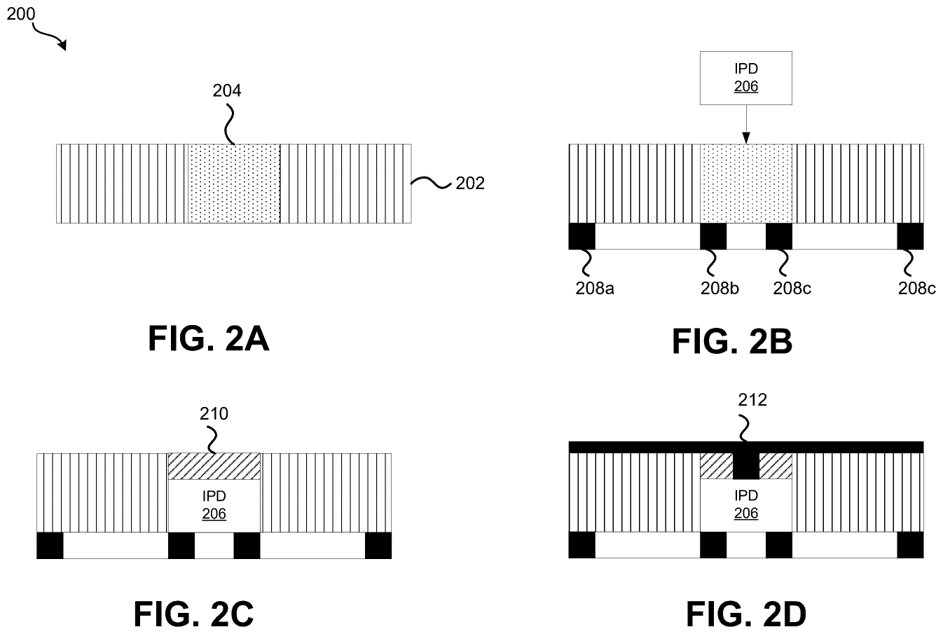

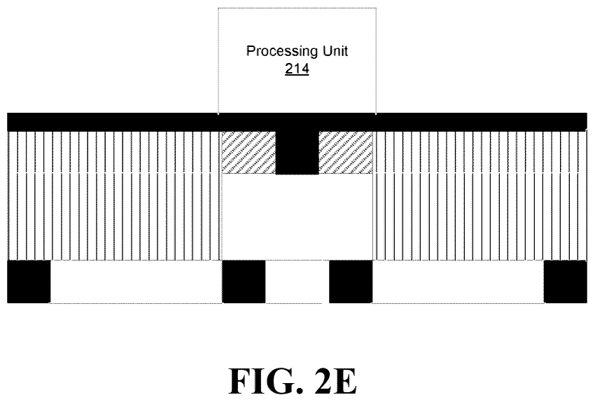

At step 102, the method 100 may include providing a substrate 202 with a cavity 204, as shown in FIG. 2A. The cavity 204 may be formed in the substrate, after the substrate 202 is formed. For example, the cavity 204 may be formed in the substrate 202 via laser ablation, etching, mechanical drilling, or any bother suitable process for removing material. In some embodiments, the substrate 202 may be manufactured to already include the cavity 204, such that no material is removed to form the cavity 204. The substrate 202 may include silicon, glass, silica, or any other suitable material. The substrate 202 may also include one or more metal films (e.g., barium titanate), deposited on a surface of the substrate 202. The cavity 204 may include a width of about0.15 mm,0.25 mm,0.5 mm, 1 mm, 1.5 mm, and/or 2 mm. The cavity 204 may also include a depth (into the page as seen in FIG. 2A) of about 1 mm, about 2 mm, about 3 mm, about 4 mm, about 5 mm, and or greater than 5 mm.

At step 104, the method 100 may include inserting an IPD 206 into the cavity 204 of the substrate 202. The IPD 206 may include one or more capacitors, inductors, and/or other such components. The IPD 206 may also be an array of integrated passive devices, with various components integrated into a unitary package. For example, the cavity 204 may include a width of 1 mm. The IPD 206 may comprised of 10 individual capacitors and/or inductors with a width of 100 microns each. Each of the individual devices within the IPD 206 may include respective terminals, or some or all of the individual devices may share terminals. Furthermore, the individual devices within the IPD 206 may be thinner than traditional LC components (as described below). The individual devices each include similar properties to traditional LC components, however. Thus, by vertically mounting the individual devices within the IPD 206, the capacitive and/or inductive density (together, “storage density”) may be many ten times greater than if the IPD 206 was a traditional IPD.

Furthermore, the IPD 206 may be manufactured to any depth as allowed by the cavity 204. For example, the depth of the cavity 204 may be 5 mm. Thus, the IPD 206 may include a depth of about 5 mm as well. The thin individual devices within the IPD may be manufactured in such a way that the depth is not inhibited by manufacturing limitations, further increasing the performance of the IPD 206 per unit area.

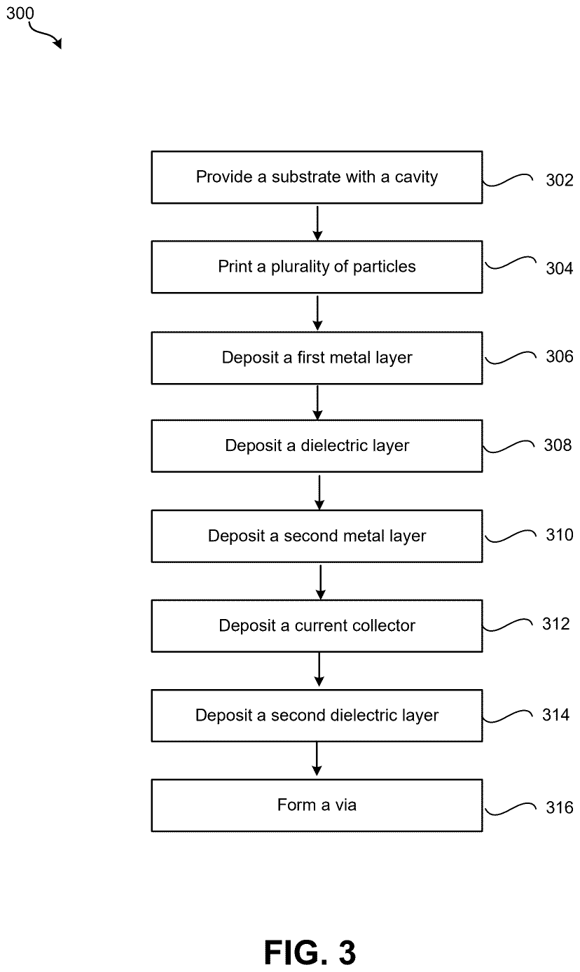

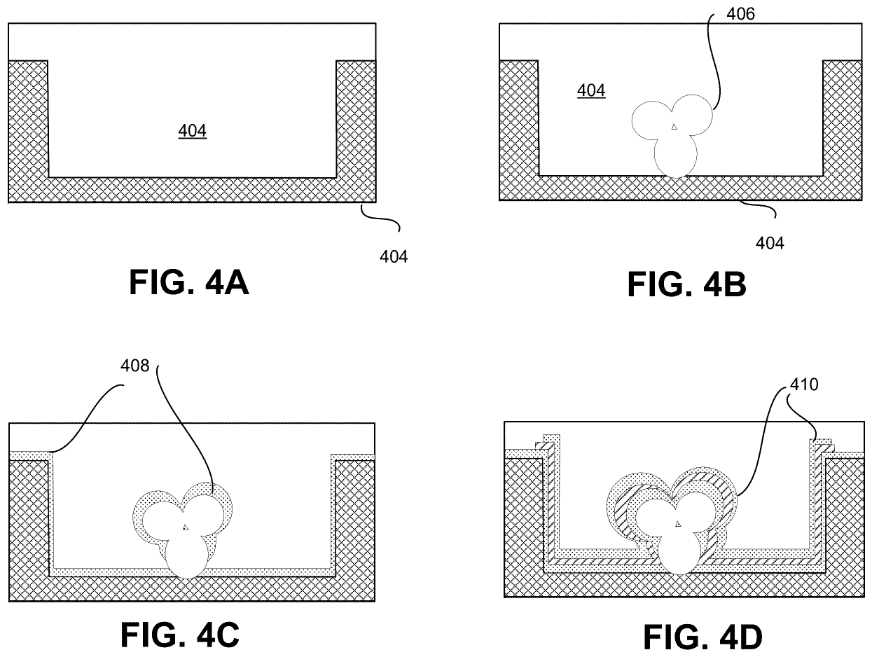

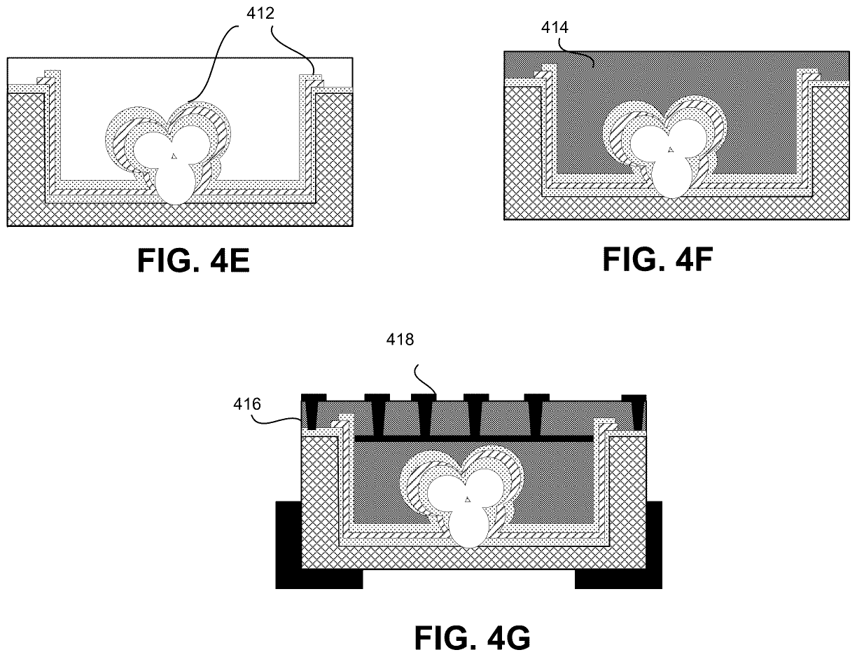

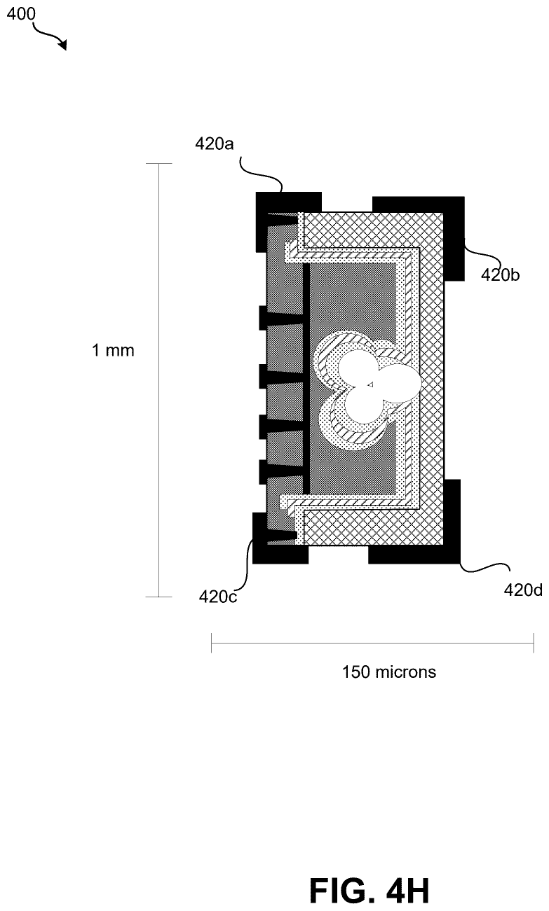

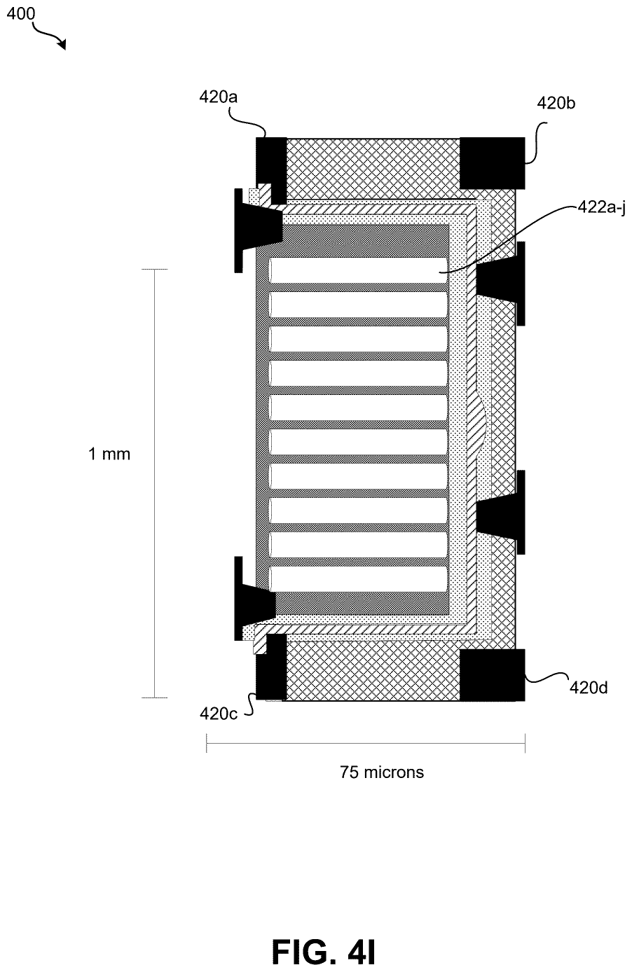

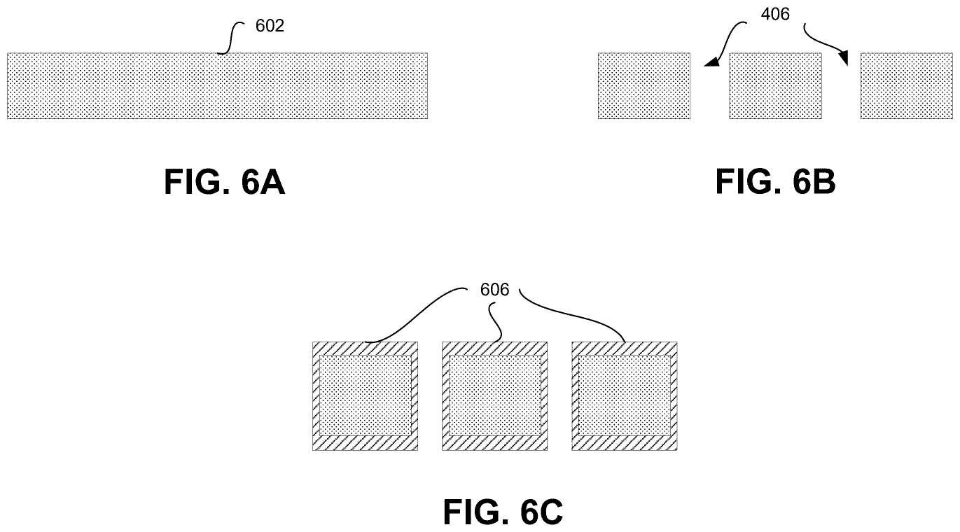

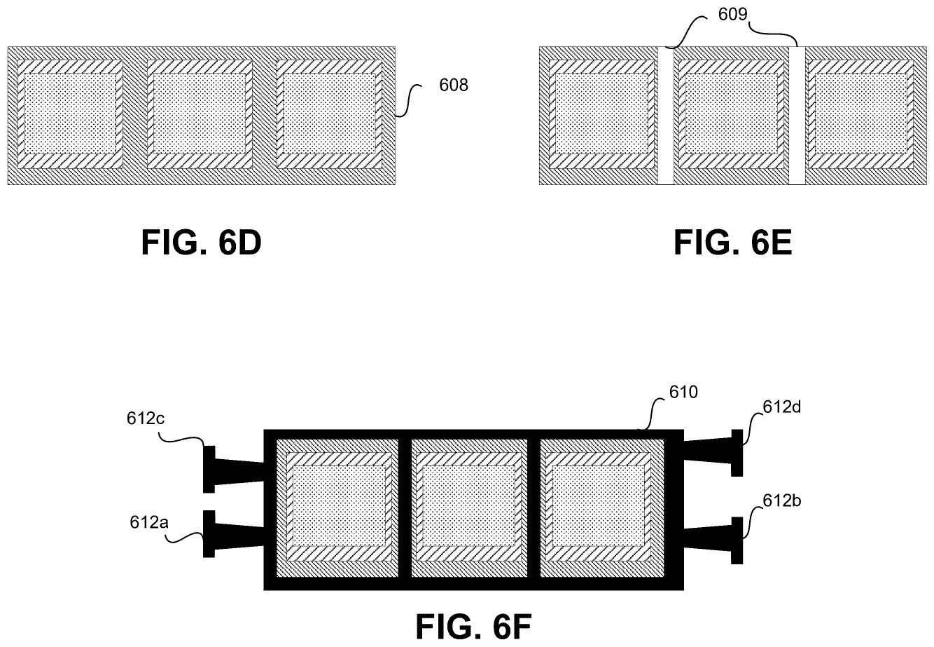

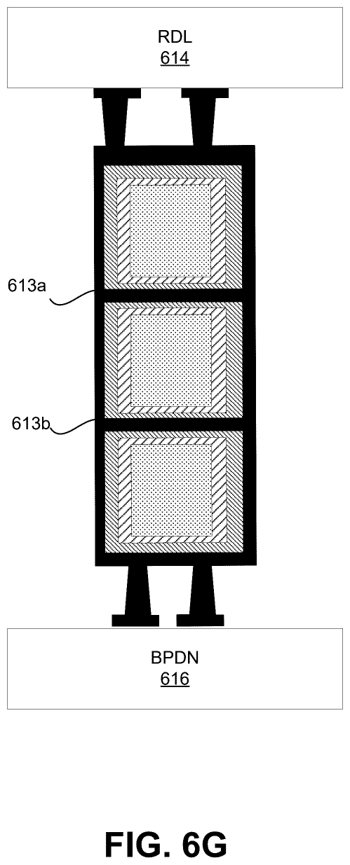

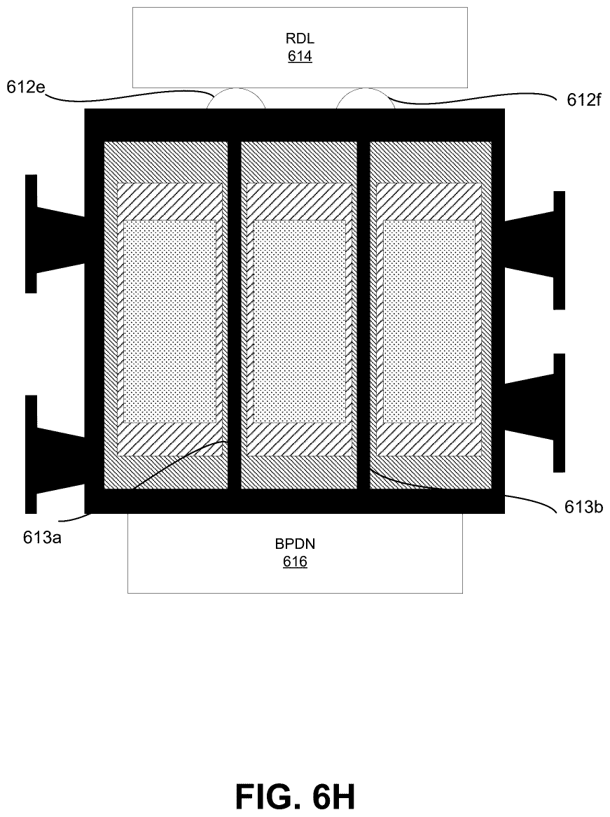

In some embodiments, the IPD 206 may be pre-manufactured. For example, in a separate process, a micro-or nano-scale Bryce capacitor may be formed (as shown below in FIGS. 3-4G). The Bryce capacitor may then be packaged with other capacitors (e.g., other Bryce capacitors, MLCCs, etc.) to form the IPD 206. Additionally or alternatively, the IPD 206 may include thin-film inductors (as shown in FIGS. 6A-6F). Then one or more thin-film inductors and/or capacitors may form a multiterminal IPD 206.

A backside power delivery network (BPDN) 208a-d may be formed on the substrate 202. The BPDN 208a-d may include one or more metal pathways for transmitting electrical signals (e.g., power, data, etc.) from a backside of the semiconductor device to a frontside of the semiconductor device. The IPD 206 may be electrically connected to some or all of the BPDN 208a-d. For example, as seen in FIG. 2B, the BPDN 208b-c (or connections 208b-c) may be connected to a power source (not pictured here). The IPD 206 may therefore receive signals from the power source in order to provide power to a component during operation.

At step 106, a polymer layer 210 may be deposited to the cavity 204 and/or the substrate 202, as seen in FIG. 2C. The polymer layer 210 may be a dielectric layer and/or an insulating layer. The polymer layer may include alumina, zirconia, barium titanate, hafnium zirconium oxide, hafnium silicate, plastics, ceramics, or any other suitable dielectric. The polymer layer 210 may be formed via sputtering, VLD, ALD, or any other suitable method.

The polymer layer 210 may then be planarize, providing a flat surface on a top-side of the semiconductor device 200. For example, a height of the cavity 204 may be 1.1 mm. A height of the IPD 206 may be 1 mm. The polymer layer 210 may then fill any space left in the cavity 204 after the IPD 206 is embedded. Thus, the polymer layer 210 may not aid in securing the IPD 206 within the cavity 204, but also provide electrical isolation between the IPD 206 and other components within the semiconductor device 200. The polymer layer 210 may then be smoothed to create a flat surface with the substrate 202.

At step 108, the method 100 may include forming a metal layer 212 on the substrate 202 and/or the polymer layer 210, as seen in FIG. 2D. The metal layer 212 may also extend through the polymer layer 210 to form an electrical connection to the IPD 206. Some or all of the metal layer 212 may therefore form interconnects for delivering power from the BPDN to the devices via the IPD 206. In some embodiments, the metal layer 212 may include multiple connections to various portions of the IPD 206. Each of the multiple connections may access a different terminal of the IPD 206. Various domains of the IPD 206 may therefore access the IPD 206 without the need of creating separate IPDs for each domain dependent on function, frequency, power, etc. By enabling multiterminal access, more space may be available for power/ground networks that bypass the LC devices within the IPD 206 (i.e., powering other components of the semiconductor device 200).

At step 110, the method 100 may include providing a processing unit 214 to the semiconductor device 200 such that the processing unit 214 is in electrical contact with the IPD 206, as seen in FIG. 2D. The processing unit may include one or more processors (e.g., GPUs), FPGAs, ASICs, and other suitable devices. Because the IPD 206 may have a high power density as compared to traditional IPDs, more space may be available within the semiconductor device 200 for other vias (data, power, etc.) while still providing efficient, stable power to the processing unit 214.

FIG. 3 illustrates a flowchart of a method 300 for forming a vertically mounted capacitor, according to certain embodiments. The method 300 may be performed, in whole or in part, to produce some or all of the systems and device described herein. Some or all of the steps of the method 300 may be performed in a different order than is presented and/or combined with other steps. In some embodiments, some steps of the method 300 may be skipped altogether.

At step 302, the method 300 may include proving a substrate 402, as shown in FIG. 4A. The substrate 402 may include a cavity 404. The cavity 404 may be formed in the substrate, after the substrate 402 is formed. For example, the cavity 404 may be formed in the substrate 402 via laser ablation, etching, mechanical drilling, or any bother suitable process for removing material. In some embodiments, the substrate 402 may be manufactured to already include the cavity 404, such that no material is removed to form the cavity 404. The substrate 402 may include silicon, glass, silica, or any other suitable material. The substrate 402 may also include one or more metal films (e.g., barium titanate), deposited on a surface of the substrate 402.

At step 304, the method 300 may include printing a plurality of particles 406 on the substrate 402, as shown in FIG. 4B. In the example shown in FIG. 4B, the plurality of particles 406 may be printed in the cavity 404 of the substrate 402. The plurality of particles 406 may be printed via a screen printing process and/or a spin coating process. One or more masks (e.g., a shadow mask) may be utilized during the screen printing and/or spin coating process. The plurality of particles 406 may additionally or alternatively be formed separately from the substrate 402 and provided via one or more dispensing processes such as screen-printing, inkjet printing or other processes.

In some embodiments, silica templates may be used to form the plurality of particles 406 porous. Deionized water surface-treated silica nanoparticles (size ranging from 300 nm to 500 nm) are deposited as thin films on the substrate 402. The nanoparticles may fabricated using screen-printed square patterns after a stencil lift-off and/or via direct screen-printing. The screen printing process may utilize binders such as Polyvinyl Alcohol (PVA), methyl or ethyl cellulose, and/or acrylates. The addition of polymer acrylate binders or Polyvinyl Alcohol (PVA) to may prevent cracking from drying stresses and increase mechanical integrity.

The plurality or particles 406 may be substantially spherical and include inorganic materials such as glass, silica, ceramic, polymers, barium titanate, or any other suitable material. The plurality of particles 406 may be porous, allowing any materials subsequently applied to the plurality of particles 406 to at least partially penetrate an outer surface of the plurality of particles. The porosity of the plurality of particles 406 and the substantially spherical shape may provide a larger surface area per unit volume/area when compared to other types of capacitors (e.g., trench capacitors, MLCCs, etc.). The plurality of particles 406 may also include carbon-or other inorganic particle-loaded polymers. The plurality of particles 406 may completely or partially fuse to form porous electrodes at relatively low temperatures. The polymer coating of inorganic core-shell particles may allow the core-shell particles (e.g., the plurality of particles 406) to fuse at low temperatures.

The plurality of particles 406 may be at least partially fused together via sintering or any other suitable process. The plurality of particles 406 may be fused in a regular pattern, or randomly fused together. Furthermore, while three individual particles are shown in FIGS. 2A-G, any number of particles may be included in the plurality of particles 406 (e.g., 10, 40, 300, etc.). In some embodiment, the plurality of particles 406 may not be a plurality, and instead one particle.

At step 306, the method 300 may include depositing a first metal layer 408 on the substrate 402 and the plurality of particles 406, as shown in FIG. 4C. The first metal layer 408 may be formed via sputtering, vapor layer deposition (VLD), atomic layer deposition (ALD), or any other suitable method. The first metal layer 408 may include titanium nitride, titanium, copper, cobalt, ruthenium, ruthenium oxide, titanium, oxygen, or any other suitable material. The first metal layer 408 may be deposited to a thickness of about 5 nm, about 10 nm, about 15 nm, about 40 nm, about 25 nm, about 30 nm, about 40 nm, and/or about 50 nm. The first metal layer 408 may be a conducting layer, such that the first metal layer 408 may act as an electrode in a capacitor. Depositing a dielectric directly on metal (e.g., copper or nickel) can cause interdiffusion between the dielectric and the metal and cause reliability issues. In some embodiments, a titanium nitride layer may be disposed over the first metal layer 408 and/or over the plurality of particles 406. The titanium nitride layer may act as a conduction and interdiffusion barrier, preventing interdiffusion between the dielectric and the mating surfaces.

The first metal layer 408 may at least partially coat the plurality of particles 406, For example, the first metal may 408 may cover 300% of the plurality of particles 406, or may cover about 90%, about 80%, about 70%, and/or about 60%. The first metal layer 408 may cover each particle of the plurality of particles 406 evenly, or each particle of the plurality of particles 406 may be variably coated. Because of the porous nature of the plurality of particles 406, at least some of the material of the first metal layer 408 may penetrate an outer surface of some or all of the plurality of particles 406. Thus, when acting as an electrode, the plurality of particles 406 coated in the first metal layer 408 may have a greater surface area than a capacitor taking up equal space. Thus, the capacitive density associated with a capacitor utilizing the plurality of particles 406 may be greater than other capacitor types. Areas of the cavity 404 not occupied by the plurality of particles 406 may be covered by the first metal layer 408. Areas of the substrate 402 outside of the cavity 404 may also be covered by the first metal layer 408.

At step 308, the method 300 may include depositing a dielectric layer 410 on the first metal layer 408, as shown in FIG. 4D. The dielectric layer 410 may include alumina, zirconia, barium titanate, hafnium zirconium oxide, hafnium silicate, plastics, ceramics, or any other suitable dielectric. The dielectric layer 410 may be formed via sputtering, VLD, ALD, or any other suitable method. The dielectric layer 410 may be formed to a thickness of about 2 nm, about 5 nm, about 8 nm, about 10 nm, about 12 nm, about 15 nm, and/or about 40 nm. Certain mixed component oxides may show an amorphous nature when deposited but may crystallize when treated at high temperatures in oxygenating or ozone plasma. Such films may show ferroelectric properties and lead to high permittivity. This may provide a high capacitance density. However, these films may be sensitive to temperature and voltage bias and limit long term reliability. As described herein, amorphous structures may be preferred in spite of any compromise in permittivity.

The dielectric layer 410 may be deposited on the first metal layer 408 to completely cover the plurality of particles 406 and/or other areas of the substrate 402. For example, areas of the cavity 404 not occupied by the plurality of particles 406 may be covered by the dielectric layer 410. Areas of the substrate 402 outside of the cavity 404 may also be covered by the dielectric layer 410.

At step 310, the method 300 may include depositing a second metal layer 412 on the dielectric layer 410, as shown in FIG. 4E. The second metal layer 412 may include titanium nitride, polysilicon, titanium, nickel, iron, copper, cobalt, ruthenium, ruthenium oxide, or any other suitable material. The second metal layer 412 may include the same material as the first metal layer 408 (e.g., titanium nitride) or may include different materials. The second metal layer 412 may be deposited to cover all or substantially all of the dielectric layer 410, both over the plurality of particles 406 and other areas of the substrate 402. The second metal layer 412 may be deposited to a thickness of about 5 nm, about 10 nm, about 15 nm, about 40 nm, about 25 nm, about 30 nm, about 40 nm, and/or about 50 nm.

The second metal layer 412 may serve as an electrode of a capacitor. After the deposition of the second metal layer 412, the plurality of particles 406 may be coated in conducting layers (e.g., the first and second metal layers 408 and 412) separated by a dielectric layer 410. Thus, the configuration described above may form a Bryce capacitor, providing increased capacitive performance for semiconductor and other devices.

At step 312, the method 300 may include depositing a current collector 414 on the second metal layer 412, as shown in FIG. 4F. The current collector 414 may be deposited by ALD or VLD or may be microassembled and placed on the second metal layer 412. The current collector 414 may include polysilicon, nickel, iron, copper, titanium, ruthenium, ruthenium oxide, conducting polymers (PEDOT-PSS), or any other suitable material. The current collector 414 may substantially fill the cavity 404, effectively planarizing the plurality of particles 406. The current collector 414 may therefore provide a substantially flat surface on which to further process the capacitor being manufactured via the method 300. In other words, the current collector 414 may be deposited over the both electrodes of the Bryce capacitor. The current collector 414 may also include a metal paste containing silver, graphene, and/or other suitable materials. The current collector 414 (and paste) may aid in collecting current from the Bryce capacitor and distributing the current to a power delivery network.

At step 314, the method 300 may include removing a portion of the dielectric layer 410, and the second metal layer 412 (collectively, the “layers”), as shown in FIG. 4F. The layers may be removed from one or more regions adjacent to the cavity 404. The layers may be removed via a chemical etching process, reactive ion etching process, or other suitable method. The first metal layer 408 may therefore be exposed in the one or more regions adjacent to the cavity 404. Thus, as described below, the one or more regions may form contacts for a power delivery system.

At step 316, the method 300 may include depositing an epoxy layer 416 on the Bryce capacitor, such that the Bryce capacitor is planarized, as shown in FIG. 4G. The epoxy layer 416 may include a B-type epoxy or other such material. The epoxy layer 416 may be formed via injection, ALD, VLD, lithography, or any other suitable process. The epoxy layer 416 may also be deposited such that the epoxy layer 416 can accept one or more vias.

At step 318, the method 300 may include forming a metal pathway 418, or via, on top of the epoxy layer 416 and extending through the epoxy layer 416 to be in electrical contact with one or more of the first metal layer 408 and/or the current collector 414. More than one via 418 may be formed, as is shown in FIG. 2G. For example, the via(s) 418 may be in contact with the first metal layer 408 in the regions adjacent to the cavity 404 (i.e., the contacts formed during the etching process at step 314). The via(s) 418 may also be in contact with the current collector 414. As shown in FIG. 2G, the via(s) 418 may be all be connected to each other. In other words, the first metal layer 408 and the current collector 414 may be connected to each other by the via(s) 418. In other embodiments, each of the first metal layer 408 and the current collector 414 may be electrically isolated from one another, except for the capacitive properties of the Bryce capacitor (e.g., the plurality of particles 406 and corresponding metal and dielectric layers).

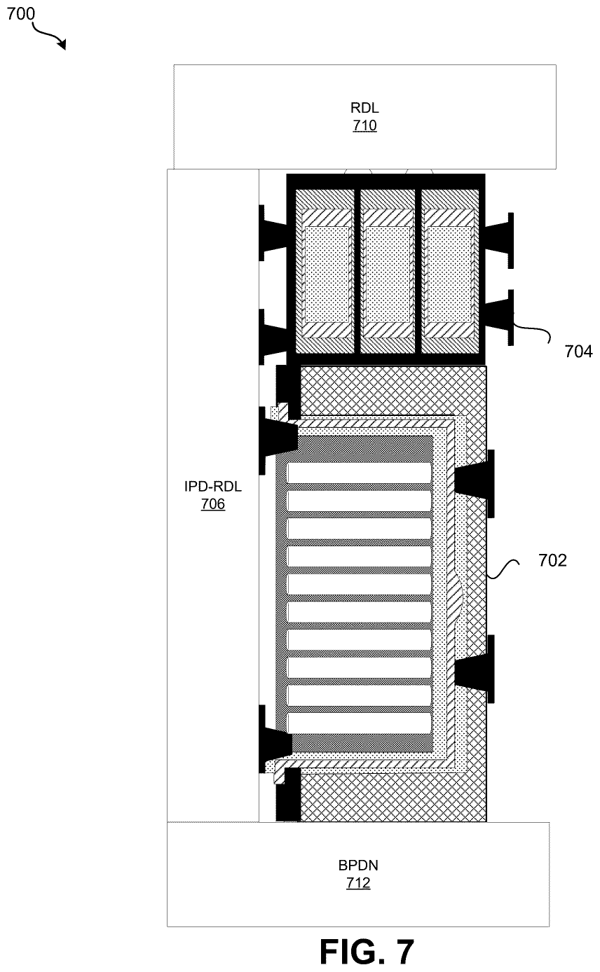

FIG. 4H illustrates the capacitor 400 with edge mounted terminals 420a-d, according to certain embodiments. The edge mounted terminals 420a-d may be a portion of the metal pathways 418. The edge mounted terminals 420a-d may be formed as part of the method 300 as an additional step. By forming the capacitor 400 horizontally with the edge mounted terminals 420a-d, the capacitor 400 may be rotated and inserted into a semiconductor device vertically. The vias 418 (in FIG. 4G) may then be connected to an on-IPD redistribution layer (RDL), as shown in FIG. 7. The edge-mounted terminals 420a-d may then be used to connect the capacitor 400 to a device RDL (on the top) and a backside power delivery network (BPDN) at the bottom.

A height of the capacitor 400 may be about 1 mm as seen in FIG. 4H. In other embodiments, the height of the capacitor 400 may be about 0.5 mm, about 0.75 mm, about 1.25 mm, about 2 mm, and/or greater than 2 mm. A width of the capacitor 400 may be about 50 microns, about 75 microns, about 100 microns, about 150 microns, and/or about 225 microns (or anywhere in between). As discussed above, traditional capacitors may have roughly cubic dimensions; mounting these capacitors vertically therefore may not provide significant gains in capacitive density. Because the width of the capacitor 400 may be smaller than the width of traditional capacitors, the edge mounted terminals 420a-d may enable the capacitor 400 to be mounted vertically within a cavity of a chip (e.g., the IPD 206 in the cavity 204 in FIGS. 2A-2D. Thus, more capacitors such as the capacitor 400 may be embedded in cavity, greatly increasing the capacitive density of the BPDN. For example, using the Bryce capacitor 400, the IPD 206 may include a capacitive density within a range of 10-100 microfarads per millimeter square (e.g., 25-50 μF/mm²).

In some embodiments, the IPD may be fabricated in the lateral configuration with shallow thinness (50-200 microns) but with larger width and length (200-1500 microns). Terminations may be pulled to the edge of the device and accessed from the vertical mounting. The devices may then be mounted in the cavity with vertical contacts that are extended from the lateral configuration. Therefore, after vertical mounting, the on-IPD interconnects may be facing to the side while the processor and BPDN access contacts may be from the top or bottom (e.g., as shown in FIG. 7). Fabricating thin shallow devices with lateral configuration, and vertical embedding may be beneficial because manufacturing may be easier with shallow cavities.

FIG. 4I illustrates a capacitor 401 with carbon nanotubes 422a-J, according to certain embodiments. The capacitor 401 may be formed using the same (or similar) process as the capacitor 400, above. The carbon nanotubes 422a-f may be formed vertically within the body of the capacitor 401. The carbon nanotubes 422a-f may be grown separately, with or without a carrier, then diced to a desired length (e.g., 0.5 mm, 0.75 mm, etc.). The carbon nanotubes may then be mounted to the edge mounted contacts 420a-d. The width of the capacitor 401 may be within a range of about 60 microns to about 100 microns. Because of the electrical properties of the carbon nanotubes 422a-f, the same capacitance per unit may be achieved with less width than even the capacitor 400, let alone traditionally mounted capacitors. Thus, the capacitive density of the capacitor 401 may be even greater than that of the capacitor 400.

In the key embodiments in this application, the high surface area architectures (nanowires, nanotubes, nanofibers, nanoparticle electrodes) may be deposited in thae lateral configuration in the cavities with shallow thinness (50-200 microns) but with larger width and length (200-1500 microns). The devices may then be mounted in the cavity with vertical contacts that are extended from the nanoelectrode architectures from the lateral configuration. In this approach, interconnects are extended to the edge of the device and accessed from the vertical mounting. Therefore, after vertical mounting, the on-IPD interconnects may be facing to the side while the processor and BPDN access contacts may be from the top or bottom. Fabricating thin shallow devices with lateral configuration, and vertical embedding may be beneficial because manufacturing may be easier. By utilizing thin carriers and embedding in shallow cavities, vertical mounting may occupy smaller footprints.

Although FIGS. 4A-4I illustrates Bryce capacitors, capacitors with carbon nanotubes, metal nanofibers, silicon trenches, silicon nanowires, aluminum nanowires, etc., it should be understood that other types of capacitors may also be formed. For example, the capacitor 400 may include one or more of a metal nanowire, a carbon nanofiber, and/or a carbon nanotubes. Additionally or alternatively, the capacitor 400 may include an MLCC. Typical MLCCs achieve 5 microfarad/mm² with 100 micron width. However, MLCC's that are edge mounted may provide a capacitive density of 5 microfarad/mm². In other words, edge access may provide a 10× increase in capacitive density. The edge-mounted MLCC may include, terminals for both polarities on the same edge. In some embodiments, the MLCC may include multiple bipolar terminals with a fine pitch. This may lower loop inductances created by the MLCC, improving frequency stability of various components within an IPD array.

To create the multiple bipolar terminals electrodes of corrugated extensions. The corrugated extensions (grooves) from alternate electrodes may be displaced with respect to each other such that the grooves from the alternate electrodes are aligned. The extensions may then be terminated using edge metallization, such that the MLCCs may be vertically mounted.

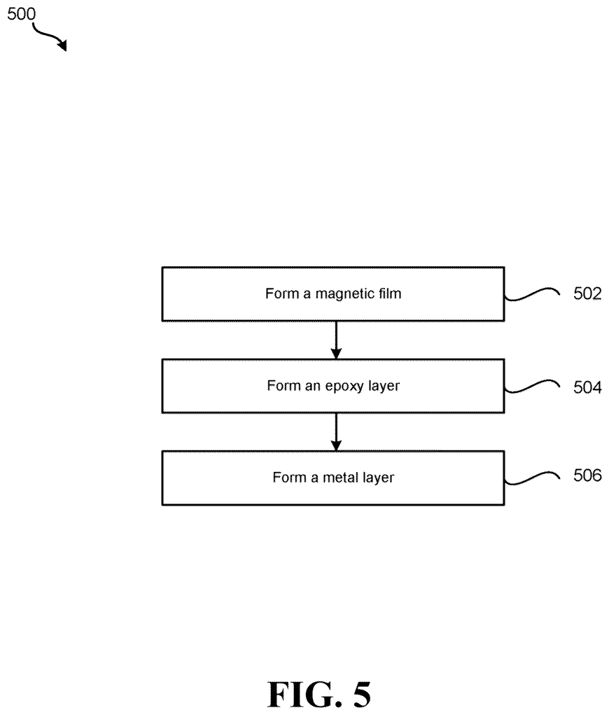

FIG. 5 illustrates a flowchart of a method 500 for forming a vertically mounted inductor, according to certain embodiments. Steps of the method 500 may be performed in a different order than is shown in FIG. 1 and/or combined with other steps of the method 500. In some embodiments, some of the steps of the method 500 may be skipped altogether.

At step 502, the method 500 may include forming a magnetic film 606 on a flexible core 602. In FIG. 6A, a flexible core 602 may be provided. The flexible core 602 may comprise polyimide, glass, liquid crystal polymer, fluoropolymer, Molypermalloy powder cores, High Flux, kool Mu®/Sendust, or other suitable core materials. The flexible core 602 may have a thickness of about 15 μm, about 20 μm, about 30 μm, about 35 μm, or about 40 μm. The flexible core 602 may be an “off-the-shelf” product or may be manufactured as part of the method 500. During a manufacturing process, the flexible core 602 may be supported by a framework, grid frame, or other suitable device. The framework may provide a template for features to be formed on the flexible core 602, such as patterning for a deposition or etching process, guides holes for drilling or ablation, and/or any other such process.

As shown in FIG. 6B, first vias 604 may be formed in the flexible core 602. The first vias 604 may be formed using a laser, mechanical drill, or formed via an etching and/or ablation process. The first vias 604 may include a diameter of about 10 μm, about 15 μm, about 20 μm, about 25 μm, about 30 μm, about 40 μm, about 50 μm, about 60 μm, and/or about 70 μm. In some embodiments, all of the first vias 604 include the same diameter. In other embodiments, the first vias 604 may include different diameters. In either case, the first vias 604 may extend through a top and bottom side of the flexible core 602.

As shown in FIG. 6C, the magnetic film 606 may be formed on multiple sides of the flexible film 602. The magnetic film 606 may be formed on sidewalls of the first vias 604. The magnetic film may be deposited to a thickness of about 10 μm, about 15 μm, about 20 μm, about 25 μm, or about 30 μm. The magnetic film 606 may include nickel, iron, cobalt, zirconia, tantalum, and/or any other suitable material. The magnetic film 606 may include a single material or may include combinations and alloys of any or all of the aforementioned materials. In some embodiments, the magnetic film 606 may be formed by sputtering one or more materials on the flexible core 602. In other embodiments, the magnetic film 606 may be formed by other physical vapor deposition (PVD) techniques such as e-beam evaporation, atomic layer deposition (ALD), or any other type of deposition. In some embodiments, multiple layers of magnetic film 606 may deposited via sputtering. The multiple layers of magnetic film 606 may been interspersed with a thin oxide of a material such as zirconia, silica or others. In some embodiments, a single oxide layer may be formed on the magnetic film 606. A single oxide layer may serve as a dielectric and aid in isolating the magnetic film 606 from other layers of the inductor.

At step 504, the method 500 may include forming a dielectric layer 608 on the magnetic film 606, as shown in FIG. 6D. The dielectric layer 608 may include materials such as epoxy, polyimide, silicones, and/or siloxanes. The dielectric layer 608 may be formed to a thickness of about 5 μm, about 10 μm, about 15 μm, or about 20 μm. The dielectric layer 608 may be formed on the top side and bottom side of the flexible core 602. The dielectric layer 608 may also be formed in the first vias 604. The dielectric layer 608 may completely or partially fill some or all of the first vias 604. Thus, the dielectric layer 608 may isolate the flexible core 602 and the magnetic film 606. The flexible core 602 and the magnetic film 606 may therefore be thought of as a magnetic core of the inductor.

The dielectric layer 608 may include one or more polymers or other suitable materials. The dielectric layer 608 may include a dielectric material such as polypropylene, cyclic transparent optical fluoropolymer (CYTOP), polypropylene-co-1-butene, or other suitable polymers and/or materials. The dielectric layer 608 may planarize the magnetic film 606. For example, forming the magnetic film 606 may create imperfections or an uneven surface. The dielectric layer 608 may be formed such that the imperfections are filled in and/or such that a surface of the dielectric layer 608 is even.

In some embodiments, the method may include forming second vias 209 through the dielectric layer 608, as shown in FIG. 6E. The second vias 209 may correspond to the first vias 604, passing through the same pathway as the first vias 604. Thus, each of the second vias 209 be a cavity surrounded by a dielectric layer (e.g., the dielectric layer 608) and the magnetic film 606. The second vias 209 may be formed using a laser, mechanical drill, or formed via an etching and/or ablation process. The second vias 209 may include a diameter of about 10 μm, about 15 μm, about 20 μm, about 25 μm, about 30 μm, about 40 μm, and/or about 50 μm.

At step 106, the method 500 may include forming a metal layer 610 on at least a portion of the dielectric layer 608, as shown in FIG. 6F. The metal layer 610 may include copper, silver, nickel, and/or any other suitable metal. The metal layer 610 may be formed via PVD, ALD, sputtering, and/or other suitable deposition processes. The metal layer 610 may additionally or alternatively be formed via an electroplating process. For example, the metal layer 610 may be formed by depositing a metal seeding layer via PVD, then electroplating the metal layer 610 on the metal seeding layer. The metal layer 610 may be formed to a thickness of about 5 μm, about 10 μm, about 15 μm, about 20 μm, or about 30 μm.

The metal layer 610 may be formed on the top side and the bottom side of the inductor and within the second vias 609 such that the second vias 609 are completely filled. The metal layer 610 may therefore form windings (e.g., a copper winding) surrounding the magnetic core (e.g., the flexible core 602 and the magnetic film 606). The windings and the magnetic core may form components of the inductor. The dielectric layer 608 may isolate the magnetic core from the windings, improving the performance of the inductor. In some embodiments, the windings may form a toroidal shape (i.e., forming a toroidal inductor). As discussed above, a toroidal shape may provide for greater inductance and/or other performance metrics of an inductor.

The metal layer 610 may be formed via electroplating. Thick and low-resistance copper structures may be created utilizing standard plating formulations. The electroplating may utilize a current bus plane that is either deposited with PVD (e.g., sputtering) or a chemical solution processing (electroless plating). Since the current bus plane facilitates the plating of copper by acting as a seed, this plane may be referred to as a seed layer. If the seed layer is deposited by a sputtering process, the seed layer offers certain advantages with tool supply chain management as the magnetic film 606, isolation layer (e.g., an oxide layer. A dielectric layer, etc.) and seeding may be formed in the same tool or toolset at semiconductor foundry level.

Terminals 612a-b may be formed on one or both lateral sides of the metal layer 610 via edge metallization. The terminals 612a-b being mounted on the lateral sides of the metal layer 610 may allow the inductor to be vertically mounted within a cavity of a substrate (such as the cavity 204 in FIGS. 2A-2D). The inductor may include a width within a range of 100 microns to about 200 microns (e.g., 150 microns). The small width of the inductor and the ability to be vertically mounted may allow the inductor to provide an inductive density of about 40 nH/mm². The inductor may be a toroidal inductor, a solenoidal inductor, or any other such configuration.

In FIG. 6G, the inductor may be mounted within a semiconductor device to connect to an RDL 614 and a BPDN 616. The metal layer 610 filling the vias 609a-b may be the windings of the inductor. Because of the orientation of the inductor during the manufacturing process, however, the width of each of windings 613a-b may be limited. Thus, the DC resistance of the windings 613a-b may be relatively high, limiting the amount of power that may be provided. Additionally, the terminals 612a-b may be formed away from the windings 613a-b. Therefore, the power delivery and/or performance of the inductor may also be limited.

FIG. 6H illustrates a vertically oriented inductor 601, according to certain embodiments. The vertically oriented inductor 601 may be fully or partially formed via the method 500. In some embodiments, the vertically oriented inductor 601 may be turned either as part of the method 500 and/or when being mounted in the semiconductor device. As compared to FIG. 6G, the windings 613a-b (or the vias 609a-b) may now be vertical instead of horizontal. The orientation of the vias 609a-b may therefore allow the windings 613a-b to be formed thicker that if the vias 609a-b were oriented horizontally. Therefore, the DC resistance of the windings 613a-b may be reduced, and power delivered more effectively.

Furthermore, terminals 612e-g may be formed corresponding to the windings 613a-b. This allows the RDL 614 to be connected directly to the windings 613a-b. The terminals 612a-d may then be connected to an on-IPD RDL (as seen in FIG. 7). Because the windings 613a-b may be connected directly to the RDL 614 and/or the BPDN 616, throughput may be further increased.

FIG. 7 illustrates an IPD array 700, according to certain embodiments. The IPD array 700 may be similar to the IPD 206 in FIGS. 2A-2D. The IPD array 700 may include a capacitor 702, an inductor 704, an on-IPD RDL 706, a device RDL 710, and a BPDN 712. The capacitor 702 may be similar to the capacitor 401 in FIG. 4I, but may additionally or alternatively be any other type of capacitor (e.g., and MLCC, a Bryce capacitor, etc.). The inductor 704 may be similar to the inductor shown in FIGS. 6A-6F.

The lateral IPDs may be fabricated with interconnects on the top and bottom layers. Interconnects may not be easily formed on the edges with standard fabrication techniques. When the devices are vertically mounted, the interconnects may be extended to the edge. Vertical contacts may be formed during the embedding inside the cavities and interconnect formation after inserting inside the cavities.

To form IPD array 700, each of the capacitor 702 and the inductor 704 may be created separately using the methods 300 and 500, respectively (or some other method for other device-types). Then, the capacitor 702 and the inductor 704 may be aligned and/or stacked (e.g., to form a unitary body) according to the design needs for a semiconductor device (e.g., the semiconductor device 200). It should be understood that any number of capacitors, inductors, and/or any other device may be stacked in any order. The on-IPD RDL 706 may include a 3D interconnection process. The terminals of the capacitor and the inductor 704 may be pulled to the edge of a coupon (e.g., a carrier formation) in order to provide easy edge access and enable vertical mounting of the IPD array 700. Thus, the on-IPD RDL 706 may enable bipolar multiterminal for the IPD array 700. When embedded into a semiconductor device, therefore, multiple domains may be served using the IPD array 700.

Furthermore, because the on-IPD RDL 706 may be formed on a side of the IPD array 700, the valuable space may be saved within the RDL 710 and/or the semiconductor device as a whole. In other words, the on-IPD RDL 706 may allow the IPD array 700 to be connected directly to the device RDL 710, providing smoother power delivered at lower resistances as compared to other devices.

This approach may be extended to stacking thin layers of capacitor and inductors. The stacking of capacitors and inductors may utilize the interconnect layers over the IPDs. The interconnects on the IPDs may be extended to the edges and diced. This converts them to edge interconnects. The diced stacks may be vertically mounted inside the cavity to form the vertical contacts with the GPU/CPU and the backside power delivery network.

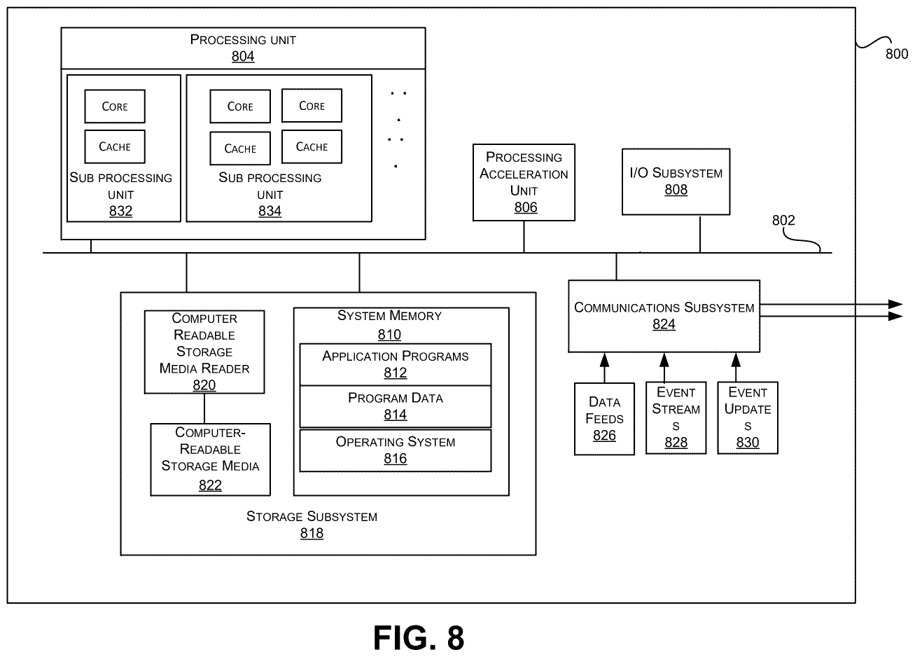

FIG. 8 illustrates an exemplary computer system 800, in which various embodiments may be implemented. The system 800 may be used to implement any of the computer systems described above. As shown in the figure, computer system 800 includes a processing unit 804 that communicates with a number of peripheral subsystems via a bus subsystem 802. These peripheral subsystems may include a processing acceleration unit 806, an I/O subsystem 808, a storage subsystem 818 and a communications subsystem 824. Storage subsystem 818 includes tangible computer-readable storage media 822 and a system memory 810.

Bus subsystem 802 provides a mechanism for letting the various components and subsystems of computer system 800 communicate with each other as intended. Although bus subsystem 802 is shown schematically as a single bus, alternative embodiments of the bus subsystem may utilize multiple buses. Bus subsystem 802 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 804, which can be implemented as one or more integrated circuits (e.g., a conventional microprocessor or microcontroller), controls the operation of computer system 800. One or more processors may be included in processing unit 804. These processors may include single core or multicore processors. In certain embodiments, processing unit 804 may be implemented as one or more independent processing units 832 and/or 834 with single or multicore processors included in each processing unit. In other embodiments, processing unit 804 may also be implemented as a quad-core processing unit formed by integrating two dual-core processors into a single chip.

In various embodiments, processing unit 804 can execute a variety of programs in response to program code and can maintain multiple concurrently executing programs or processes. At any given time, some or all of the program code to be executed can be resident in processor(s) 804 and/or in storage subsystem 818. Through suitable programming, processor(s) 804 can provide various functionalities described above. Computer system 800 may additionally include a processing acceleration unit 806, which can include a digital signal processor (DSP), a special-purpose processor, and/or the like.

I/O subsystem 808 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices that enables users to control and interact with an input device through a natural user interface using gestures and spoken commands. Additionally, user interface input devices may include voice recognition sensing devices that enable users to interact with voice recognition systems through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader, 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 800 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 800 may comprise a storage subsystem 818 that comprises software elements, shown as being currently located within a system memory 810. System memory 810 may store program instructions that are loadable and executable on processing unit 804, as well as data generated during the execution of these programs.

Depending on the configuration and type of computer system 800, system memory 810 may be volatile (such as random access memory (RAM)) and/or non-volatile (such as read-only memory (ROM), flash memory, etc.). The RAM typically contains data and/or program modules that are immediately accessible to and/or presently being operated and executed by processing unit 804. In some implementations, system memory 810 may include multiple different types of memory, such as static random access memory (SRAM) or dynamic random access memory (DRAM). In some implementations, a basic input/output system (BIOS), containing the basic routines that help to transfer information between elements within computer system 800, such as during start-up, may typically be stored in the ROM. By way of example, and not limitation, system memory 810 also illustrates application programs 812, which may include client applications, Web browsers, mid-tier applications, relational database management systems (RDBMS), etc., program data 814, and an operating system 816.

Storage subsystem 818 may also provide a tangible computer-readable storage medium for storing the basic programming and data constructs that provide the functionality of some embodiments. Software (programs, code modules, instructions) that when executed by a processor provide the functionality described above may be stored in storage subsystem 818. These software modules or instructions may be executed by processing unit 804. Storage subsystem 818 may also provide a repository for storing data used in accordance with some embodiments.

Storage subsystem 800 may also include a computer-readable storage media reader 560 that can further be connected to computer-readable storage media 822. Together and, optionally, in combination with system memory 810, computer-readable storage media 822 may comprehensively represent remote, local, fixed, and/or removable storage devices plus storage media for temporarily and/or more permanently containing, storing, transmitting, and retrieving computer-readable information.

Computer-readable storage media 822 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 800.

By way of example, computer-readable storage media 822 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD or other optical media. Computer-readable storage media 822 may include, but is not limited to, flash memory cards, universal serial bus (USB) flash drives, secure digital (SD) cards, DVD disks, digital video tape, and the like. Computer-readable storage media 822 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 800.

Communications subsystem 824 provides an interface to other computer systems and networks. Communications subsystem 824 serves as an interface for receiving data from and transmitting data to other systems from computer system 800. For example, communications subsystem 824 may enable computer system 800 to connect to one or more devices via the Internet. In some embodiments communications subsystem 824 can include radio frequency (RF) transceiver components for accessing wireless voice and/or data networks (e.g., using cellular telephone technology, advanced data network technology, such as 3G, 4G, 5G, or EDGE (enhanced data rates for global evolution), WiFi (IEEE 802.5 family standards, or other mobile communication technologies, or any combination thereof), global positioning system (GPS) receiver components, and/or other components. In some embodiments communications subsystem 824 can provide wired network connectivity (e.g., Ethernet) in addition to or instead of a wireless interface.

In some embodiments, communications subsystem 824 may also receive input communication in the form of structured and/or unstructured data feeds 826, event streams 828, event updates 830, and the like on behalf of one or more users who may use computer system 800.

By way of example, communications subsystem 824 may be configured to receive data feeds 826 in real-time from users of social networks and/or other communication services, web feeds such as Rich Site Summary (RSS) feeds, and/or real-time updates from one or more third party information sources.

Additionally, communications subsystem 824 may also be configured to receive data in the form of continuous data streams, which may include event streams 828 of real-time events and/or event updates 830, that may be continuous or unbounded in nature with no explicit end. Examples of applications that generate continuous data may include, for example, sensor data applications, financial tickers, network performance measuring tools (e.g., network monitoring and traffic management applications), clickstream analysis tools, automobile traffic monitoring, and the like.

Communications subsystem 824 may also be configured to output the structured and/or unstructured data feeds 826, event streams 828, event updates 830, and the like to one or more databases that may be in communication with one or more streaming data source computers coupled to computer system 800.

Due to the ever-changing nature of computers and networks, the description of computer system 800 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

What is claimed is:

1. A semiconductor device, comprising:
a substrate comprising a cavity;
a vertically mounted integrated passive device (IPD) disposed within the cavity of the substrate; and a a backside power delivery network, electrically connected to the vertically mounted IPD.

2. The semiconductor device of claim 1, wherein the vertically mounted IPD comprises a capacitor.

3. The semiconductor device of claim 2, wherein the capacitor comprises at least one of a sintered particle, a metal nanowire, a carbon nanofiber, a silicon trench, a silicon nanowire, an aluminum nanowire, or a carbon nanotube.

4. The semiconductor device of claim 2, wherein the capacitor is a Bryce capacitor.

5. The semiconductor device of claim 1, wherein the vertically mounted IPD comprises at least one of a solenoidal inductor or a toroidal inductor.

6. The semiconductor device of claim 1, wherein the vertically mounted IPD comprises an inductor-capacitor stack.

7. The semiconductor device of claim 1, wherein the vertically mounted IPD comprises interconnects on a side that are extended to a top and a bottom side and are configured for backside power delivery.

8. A method of manufacturing a semiconductor device with a vertically mounted IPD, comprising:
providing a substrate comprising a cavity;
inserting a vertically mounted IPD in the cavity, such that a first edge of the vertically mounted IPD is in electrical contact with a backside power delivery network (BPDN) of the semiconductor device;
depositing a polymer layer to the cavity such that the vertically mounted IPD and the polymer layer fill the cavity;
forming a third metal layer such that at least a portion of the third metal layer is in electrical contact with the vertically mounted IPD; and
connecting a processing unit to the third metal layer.

9. The method of claim 8, wherein the vertically mounted IDP is a capacitor, the method further comprising:
forming a first metal layer;
depositing a dielectric layer on the first metal layer; and
depositing a second metal layer on the dielectric layer to form the capacitor.

10. The method of claim 9, further comprising forming particles on the first metal layer.

11. The method of claim 10, wherein the particles comprise at least one of fiber-based particles, silica, silica glass, or barium titanate particles.

12. The method of claim 8, wherein the vertically mounted IPD is an inductor, the method further comprising:
providing a flexible core comprising a magnetic film;
forming a dielectric layer on the magnetic film; and
forming a metal layer on at least a portion of the magnetic film to form the inductor.

13. The method of claim 8, further comprising:
forming an inductor;
forming a capacitor;
stacking the inductor and capacitor in a unitary body to form the vertically mounted IPD.

14. A semiconductor device with a vertically mounted IPD, comprising:
a substrate comprising a cavity;
a vertically mounted IPD disposed within the cavity, the vertically mounted IPD comprising:
a capacitor comprising electrical contacts on a vertical edge of the capacitor; and
an inductor comprising electrical contacts on a vertical edge of the inductor;
a metal layer in electrical contact on a first edge of the vertically mounted IPD, the first edge in electrical contact with at least one of the electrical contacts on the vertical edge of the capacitor or the electrical contacts on the vertical edge of the inductor;
a device layer in electrical contact with the metal layer;
a backside power delivery network in electrical contact with a second edge of the vertically mounted IPD.

15. The semiconductor device of claim 14, wherein the vertically mounted IPD comprises a width within a range of 50 microns to 150 microns, inclusive.

16. The semiconductor device of claim 14, wherein the vertically mounted IPD comprises a height within a range of 0.5 mm to 1.5 mm, inclusive.

17. The semiconductor device of claim 14, wherein the vertically mounted IPD comprises a depth within a range of 1 mm to 7 mm, inclusive.

18. The semiconductor device of claim 14, wherein the capacitor is a multilayered ceramic capacitor.

19. The semiconductor device of claim 14, wherein the vertically mounted IPD comprises a capacitive density within a range of 50 microfarads per millimeter cubed to 200 microfarads per millimeter cubed.

20. The semiconductor device of claim 14, wherein the vertically mounted IPD comprises an inductance within a range of 100 nanohenry per millimeter square to about 500 nanohenry per millimeter square.
